(19) United States
(12) Patent Application Publication
(10) Pub. No.: US 2026/0328486 A1
(43) Pub. Date: Oct. 22, 2026

(54) WATER-COOLED COOLANT DISTRIBUTION DEVICE WITH ENHANCED COOLING EFFICIENCY

(71) Applicants: Dong Weon HWANG, Seongnam-si Gyeonggi-do (KR); Jae Baek HWANG, Seongnam-si Gyeonggi-do (KR); Logan Jae HWANG, Beverly Hills, CA (US); HICON CO., LTD., Seongnam-si (KR)

(72) Inventors: Dong Weon HWANG, Seongnam-si Gyeonggi-do (KR); Jae Baek HWANG, Seongnam-si Gyeonggi-do (KR); Hyung Suk PARK, Cheonan-si Chungcheongnam-do (KR); Seung Woo RHEE, Seongnam-si Gyeonggi-do (KR)

(21) Appl. No.: 19/450,696

(22) Filed: Jan. 15, 2026

(30) Foreign Application Priority Data
Jan. 15, 2025 (KR) 10-2025-0006322

(51) Int. Cl. F28D 15/00; G01R 31/28

(52) U.S. Cl. CPC F28D 15/00; G01R 31/2877

(57) ABSTRACT

A water-cooled coolant distribution device with enhanced cooling efficiency according to exemplary embodiments of the present invention may include a lower plate, an upper casing coupled to an upper portion of the lower plate, an inlet part which is coupled to the upper casing and through which a coolant is introduced from a coolant supply, an outlet part which is coupled to the upper casing and through which the coolant is discharged toward a coolant collector, a coolant storage which is disposed in the upper casing to communicate with the inlet part and stores the coolant introduced through the inlet part, and a coolant distributor disposed on an upper surface of the lower plate to distribute the coolant supplied from the coolant storage in different directions, wherein the coolant introduced sequentially through the inlet part and the coolant storage may be branched by the coolant distributor in the different directions and guided to flow to a space between the lower plate and the coolant distributor.

### CROSS-REFERENCE TO RELATED APPLICATION

This application claims priority to and the benefit of Korean Patent Application No. 10-2025-0006322, filed on Jan. 15, 2025, the disclosure of which is incorporated herein by reference in its entirety.

### BACKGROUND

### 1. Field of the Invention

The present invention relates to a water-cooled coolant distribution device for semiconductor chip testing, which has an enhanced coolant inflow and distribution structure to maximize cooling efficiency.

### 2. Discussion of Related Art

Modern electronic devices and industrial machines are designed to providing high performance and miniaturization, and importance of cooling technology for effectively managing heat generated in the devices is increasingly highlighted. Particularly, in high temperature heat generating devices such as high-power electronic devices or datacenter servers, maintaining device performance and reliability by maximizing cooling efficiency is essential.

Semiconductor chip testing is a work requiring highly precise temperature control, and when heat generated during the testing is not quickly removed, a performance evaluation result of a chip may be affected or the chip itself may be damaged. Accordingly, water-cooled cooling systems are increasingly being used to effectively manage heat generated during semiconductor chip testing. The water-cooled cooling systems provide high thermal conductivity and heat exchange efficiency, which is essential for maintaining stability and reliability of test apparatuses.

Conventional air-cooled cooling systems are widely used due to relatively simple structures and the ease of installation but are not suitable for high-power devices due to limitations in heat conduction and dissipation performance. In order to replace this, water-cooled cooling systems are introduced, which has an advantage of effectively removing heat using a coolant. The water-cooled cooling systems may more stably operate in high-power and high-density devices due to high thermal conductivity and heat exchange efficiency.

However, even in the currently used water-cooled cooling systems, there are problems related to flow distribution of a coolant. Particularly, when a coolant is not properly distributed, overheating in a specific area or cooling imbalance may occur, and thus performance of an entire system may be degraded. In order to solve such a problem, in a coolant distribution device, an efficient flow path of a coolant is designed to improve cooling efficiency. However, since it is difficult to manufacture or assemble the conventional coolant distribution device due to a complex structure, or coolant distribution efficiency thereof is low, necessity for design optimization is being raised.

### SUMMARY OF THE INVENTION

The present invention is directed to providing a water-cooled coolant distribution device for semiconductor chip testing, which has an enhanced coolant inflow and distribution structure to maximize cooling efficiency.

The present invention is directed to providing a water-cooled coolant distribution device capable of overcoming a limitation of the conventional technology through a design in consideration of the ease of manufacturing and assembly by optimizing a flow of a coolant through a systematic structure of a lower plate, an upper casing, a coolant storage, and a coolant distributor.

A water-cooled coolant distribution device with enhanced cooling efficiency according to exemplary embodiments of the present invention includes a lower plate, an upper casing coupled to an upper portion of the lower plate, an inlet part which is coupled to the upper casing and through which a coolant is introduced from a coolant supply, an outlet part which is coupled to the upper casing and through which the coolant is discharged toward a coolant collector, a coolant storage which is disposed in the upper casing to communicate with the inlet part and stores the coolant introduced through the inlet part, and a coolant distributor disposed on an upper surface of the lower plate to distribute the coolant supplied from the coolant storage in different directions, wherein the coolant introduced sequentially through the inlet part and the coolant storage is branched by the coolant distributor in the different directions and guided to flow to a space between the lower plate and the coolant distributor.

The coolant distributor may include a distribution plate and a coolant guide line formed in a central region of the distribution plate, wherein the coolant guide line may be provided as one or more nozzles having a linear shape, which pass through an upper surface and a lower surface of the distribution plate.

The inlet part may include a first inlet through which the coolant is introduced from the coolant supply, a first outlet through which the coolant is discharged toward the coolant storage, and an inlet line connecting the first inlet and the first outlet, wherein the inlet line may be provided as a curved hollow pipe to change a flow direction of the coolant introduced through the first inlet in a first direction extending horizontally to a second direction extending vertically.

A coolant guide groove for branching the coolant supplied from the coolant distributor in two directions may be formed in the upper surface of the lower plate, and the coolant guide groove may extend in a third direction perpendicular to each of the first direction and the second direction.

A length of the coolant guide groove extending in the third direction may be greater than a length of the distribution plate extending in the third direction.

The coolant guide line may be provided as a linear nozzle extending in the first direction and disposed at a location which is not aligned with the first outlet in the second direction.

A distribution plate accommodation groove for accommodating an edge portion of the distribution plate may be formed in a lower surface of the upper casing, and the distribution plate may be inserted into and coupled to the distribution plate accommodation groove.

The water-cooled coolant distribution device may further include a sealing member which is interposed between the lower plate and the upper casing to prevent leakage of the coolant, wherein the sealing member may be provided as an O-ring having a greater diameter than the coolant distributor.

A sealing member accommodation groove for accommodating the sealing member may be formed in a lower surface of the upper casing, wherein the sealing member may be inserted into and coupled to the sealing member accommodation groove.

The outlet part may include a second inlet through which the coolant flowing through the coolant distributor is introduced, a second outlet through which the coolant is discharged toward the coolant collector, and an outlet line connecting the second inlet and the second outlet, wherein the outlet line may be provided as a curved hollow pipe to change a flow direction of the coolant introduced through the second inlet in the second direction to the first direction.

The distribution plate may include a first plate which is divided by the coolant guide line and faces the first outlet and a second plate which is divided by the coolant guide line and located at a side opposite to the first plate, wherein the first plate and the second plate may be manufactured in different shapes.

The second plate may have a smaller area than the first plate so as not to be aligned with the second inlet in the second direction.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a front-side perspective view illustrating a water-cooled coolant distribution device according to exemplary embodiments of the present invention;

FIG. 2 is a cross-sectional view for describing the water-cooled coolant distribution device according to exemplary embodiments of the present invention;

FIG. 3 is a bottom-side perspective view illustrating the water-cooled coolant distribution device according to exemplary embodiments of the present invention; and

FIG. 4 is a transparency view illustrating an internal configuration of the water-cooled coolant distribution device according to exemplary embodiments of the present invention.

### DETAILED DESCRIPTION OF EXEMPLARY EMBODIMENTS

Hereinafter, detailed embodiments of the present invention will be described. The following detailed description is provided to help comprehensive understanding of methods, devices and/or systems described in the present specification. However, these are only examples, and the present invention is not limited thereto.

In descriptions of the invention, when it is determined that detailed descriptions of related well-known technology unnecessarily obscure the gist of the invention, detailed descriptions thereof will be omitted. In addition, some terms described below are defined in consideration of functions in the present invention and meanings may vary depending on a user or operator's intentions or customs. Therefore, the meanings of terms should be interpreted based on contents throughout the present specification. Terms used in detailed description are provided to only describe embodiments of the present invention and not for purposes of limitation. Unless the context clearly indicates otherwise, the singular forms include the plural forms. The terms “comprise” or “include” in the present specification specify some features, numbers, steps, operations, elements, or some or combinations thereof, but do not preclude the presence or possibility of one or more other features, numbers, steps, operations, elements, or some of combinations thereof in addition to the description.

In addition, in descriptions of components of the embodiments of the present invention, terms such as “first,” “second,” “A,” “B,” “(a),” and “(b)” may be used. The terms are only to distinguish one element from another element, and the essence, order, number, and the like of the elements are not limited thereto by the terms.

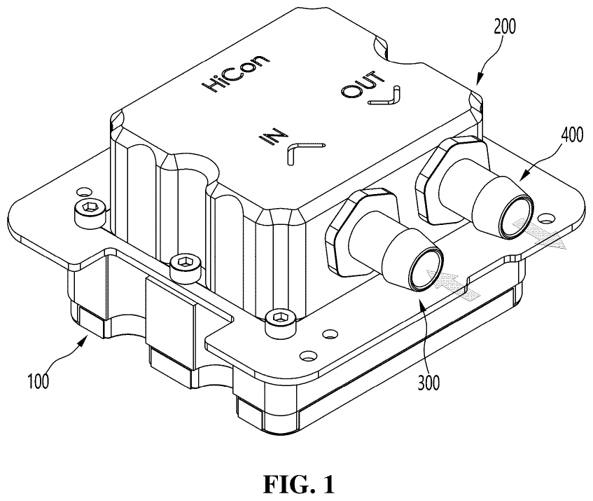

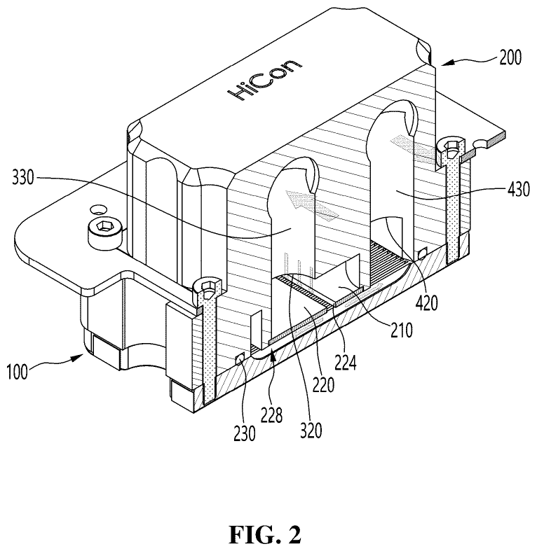

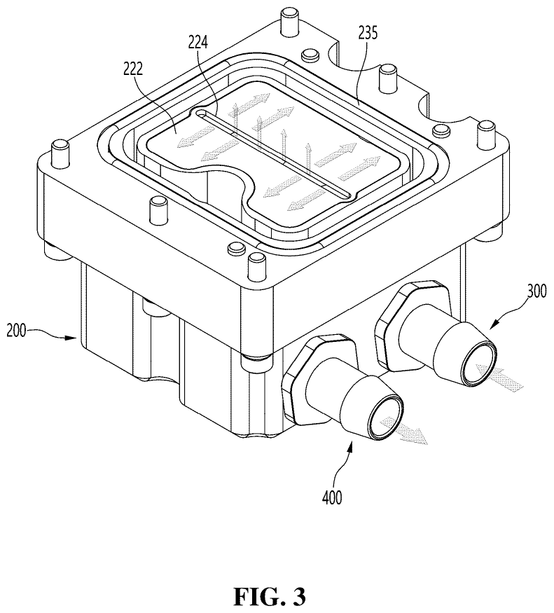

FIG. 1 is a front-side perspective view illustrating a water-cooled coolant distribution device according to exemplary embodiments of the present invention, FIG. 2 is a cross-sectional view for describing the water-cooled coolant distribution device according to exemplary embodiments of the present invention, and FIG. 3 is a bottom-side perspective view illustrating the water-cooled coolant distribution device according to exemplary embodiments of the present invention.

Referring to FIGS. 1 to 3, the water-cooled coolant distribution device with enhanced cooling efficiency according to exemplary embodiments of the present invention may include a lower plate 100, an upper casing 200 coupled to an upper portion of the lower plate 100, an inlet part 300 which is coupled to the upper casing 200 and through which a coolant is introduced from a coolant supply (not shown), an outlet part 400 which is coupled to the upper casing 200 and through which the coolant is discharged toward a coolant collector (not shown), a coolant storage 210 which is disposed in the upper casing 200 to communicate with the inlet part 300 and in which the coolant introduced through the inlet part 300 is stored, and a coolant distributor 220 which is disposed on an upper surface of the lower plate and distributes the coolant supplied from the coolant storage in different directions.

The lower plate 100 may be manufactured of a metal material (for example, aluminum or a copper alloy) with superior durability and thermal conductivity, and a fine channel for guiding a flow of the coolant may be formed in a surface of the lower plate 100, or the surface of the lower plate 100 may have an uneven structure for maximizing a contact area with the coolant.

The lower plate 100 may be provided to be coupled to the upper casing 200 to provide a sealed structure for a flow of the coolant, and the coolant distributed from the coolant distributor 220 may be uniformly distributed to the lower plate 100 and absorb heat to maximize cooling performance. The surface of the lower plate 100 may be in direct contact with a heating device (for example, an electronic device or semiconductor chip) or may serve as a heat transfer path.

The upper casing 200 may be manufactured of a metal or heat-resistant plastic (for example, polyetherether ketone (PEEK) or poly phenylene sulfide (PPS)) with lightweight and durability, and an inner portion of the upper casing 200 may be smoothly machined for an efficient flow of the coolant and include a connecting port communicating with the inlet part 300 and the outlet part 400.

The upper casing 200 may be coupled to the lower plate 100 to form a sealed space to prevent the coolant from being discharged to the outside and provided such that the coolant storage 210 is disposed in the upper casing 200 to adjust a pressure of the coolant or disperse a flow of the coolant so as to stably transmit the coolant to a next step.

The inlet part 300 may be manufactured of a metal (for example, stainless steel) or high-strength plastic with superior corrosion-resistance and heat-resistance, have a pipe shape designed to be connected to an external coolant supply, and include a thread or packing structure for fixed and sealed coupling with the upper casing 200.

The inlet part 300 may serve to receive the coolant from the coolant supply and transmit the coolant into the upper casing, and an adjustment valve or filter for adjusting a flow rate and a pressure of the coolant may be attached to the inlet part 300. The coolant introduced through the inlet part 300 may be controlled to be moved to the coolant storage 210.

In exemplary embodiments, the inlet part 300 may include a first inlet 310 through which the coolant is introduced from the coolant supply, a first outlet 320 through which the coolant is discharged toward the coolant storage 210, and an inlet line 330 through which the first inlet 310 and the first outlet 320 are connected, and the inlet line 330 may be provided as a curved hollow pipe to change a flow direction of the coolant introduced through the first inlet 310 in a first direction extending horizontally to a second direction extending vertically.

Similarly to the inlet part 300, the outlet part 400 may be manufactured of a metal or high-strength plastic in consideration of corrosion-resistance and heat-resistance, have the pipe shape designed to be connected to an external coolant collector, and include a sealed structure for stably maintaining a discharge path.

The outlet part 400 may serve to discharge the coolant which has performed a cooling process to the coolant collector, and a discharge valve or flow sensor for controlling a discharge rate of the coolant or maintaining an internal pressure balance may be installed on the outlet part 400.

In exemplary embodiments, the outlet part 400 may include a second inlet 420 through which the coolant flowing through the coolant distributor 220 is introduced, a second outlet 410 through which the coolant is discharged toward the coolant collector, and an outlet line 430 through which the second inlet 420 and the second outlet 410 are connected, and the outlet line 430 may be provided as a curved hollow pipe to change a flow direction of the coolant introduced through the second inlet 420 in the second direction to the first direction.

The coolant storage 210 may be integrally formed with an inner portion of the upper casing, and specific coating (for example, Teflon coating) may be performed on the inner portion. A capacity of the coolant storage 210 may vary according to a system design and may be designed such that the coolant is efficiently stored and maintained for a predetermined time.

The coolant storage 210 may serve to temporarily store the coolant introduced from the inlet part 300 and uniformize a flow rate and a pressure of the coolant. The coolant temporarily stored in the coolant storage 210 may be controlled to be transmitted to the coolant distributor 220 and then to uniformly flow to each channel.

The coolant distributor 220 may be disposed on the upper surface of the lower plate and include a distribution channel and a nozzle which are highly precisely machined. The coolant distributor 220 may be formed of a metal with high thermal conductivity, and an inner surface thereof may be precisely machined to reduce flow resistance of the coolant.

The coolant distributor 220 may serve to distribute the coolant transmitted from the coolant storage 210 in various directions to uniformly distribute the coolant to the entire of the lower plate 100 and may be provided to efficiently perform heat exchange by guiding the coolant along a specific path according to a predesigned thermal load condition.

In exemplary embodiments, the coolant introduced sequentially through the inlet part 300 and the coolant storage 210 may be branched in different directions by the coolant distributor 220 and guided to flow to a space between the lower plate 100 and the coolant distributor 220.

The coolant distributor 220 may include a distribution plate 222 and a coolant guide line 224 formed in a central region of the distribution plate 222, and the coolant guide line 224 may be provided as one or more nozzles having a linear shape and passing through an upper surface and a lower surface of the distribution plate 222.

In one embodiment, the coolant guide line 224 may be provided as the linear nozzle extending in the first direction and disposed at a location which is not aligned with the first outlet in the second direction.

Meanwhile, a coolant guide groove 226 for branching the coolant supplied from the coolant distributor 220 in two directions may be formed in the upper surface of the lower plate 100, and the coolant guide groove 226 may extend in a third direction perpendicular to each of the first direction and the second direction.

In exemplary embodiments, the coolant guide groove 226 may be provided as a plurality of coolant guide grooves 226, and the plurality of coolant guide grooves 226 may be sequentially disposed to be spaced a predetermined distance from each other in the first direction.

In one embodiment, a length of the coolant guide groove 226 extending in the third direction may be greater than a length of the distribution plate 222 extending in the third direction.

In addition, a distribution plate accommodation groove 228 for accommodating an edge portion of the distribution plate 222 may be formed in a lower surface of the upper casing 200, and the distribution plate 222 may be inserted into and coupled to the distribution plate accommodation groove 228.

Th water-cooled coolant distribution device according to the present invention may further include a sealing member 235 which is interposed between the lower plate 100 and the upper casing 200 to prevent leakage of the coolant from, and the sealing member 235 may be provided as an O-ring having a greater diameter than the coolant distributor 220.

In one embodiment, a sealing member accommodation groove 230 for accommodating the sealing member 235 may be formed in the lower surface of the upper casing 200, and the sealing member 235 may be inserted into and coupled to the sealing member accommodation groove 230.

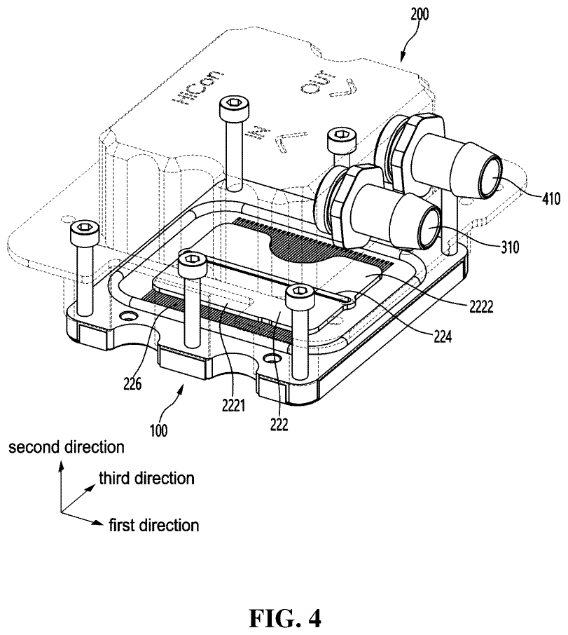

FIG. 4 is a transparency view illustrating an internal configuration of the water-cooled coolant distribution device according to exemplary embodiments of the present invention.

Referring to FIG. 4, the distribution plate 222 may include a first plate 2221, which is divided by the coolant guide line 224 and faces the first outlet 320 and a second plate 2222 which is divided by the coolant guide line 224 and located at a side opposite to the first plate 2221, that is, faces the second inlet 420, and the first plate 2221 and the second plate 2222 may be manufactured in different shapes.

Specifically, the first plate 2221 may be manufactured in a flat shape of which a portion facing the first outlet 320 is flat to provide a surface with which the coolant introduced from the first outlet 320 comes into direct contact, and the second plate 2222 may be manufactured in a curved shape of which a portion facing the second inlet 420 is open such that the coolant introduced toward the second inlet 420 flows more smoothly.

That is, the first plate 2221 may be the surface facing the first outlet 320 and provide a first contact point at which the coolant is introduced, a portion corresponding to the facing surface is manufactured as the flat shape in consideration of direct contact with the coolant, and a surface of the portion is smoothly and precisely machined.

Such a flat structure may help the coolant be quickly distributed without unnecessary resistance when introduced from the first outlet 320 and also uniformly disperse a pressure of the coolant to maximize cooling efficiency. The coolant may flow along the surface of the first plate 2221 and flow through a space between the lower plate 100 and the first plate 2221.

Meanwhile, an inner partition wall may be provided in the upper casing 200 to divide at least a portion of the second plate 2222 from the first plate 2221, and the coolant which has absorbed heat from the heating device (for example, the electronic device or semiconductor chip) disposed under the lower plate 100 may be guided to flow to the second inlet 420 through the second plate 2222.

Meanwhile, the second plate 2222 is a portion facing the second inlet 420 and has a structure designed to allow such that the coolant smoothly flows when introduced. Unlike the first plate 2221, the second plate 2222 is manufactured in the curved shape of which at least a portion is open, which guides the coolant to naturally flow along a curved line to minimize fluid resistance.

An advantage of a curved structure of the second plate 2222 is that the coolant may smoothly flow without pressure loss, thereby improving overall coolant flow performance. In addition, the second plate 2222 may have a relatively smaller area than the first plate 2221, thereby performing control such that the coolant is not concentrated in a specific region. In one embodiment, the second plate 2222 may have a smaller area than the first plate 2221 so as not to be aligned with the second inlet 420 in the second direction.

A structural difference of the first plate 2221 from the second plate 2222 acts as an important factor which balances cooling performance by guiding a flow of the coolant in a different method. Particularly, a design of the second plate 2222 which is not aligned with the second inlet 420 in the second direction contributes to natural dispersing a flow of the coolant and preventing the coolant from mixing.

As described above, according to the water-cooled coolant distribution device according to exemplary embodiments of the present invention, since the coolant is efficiently distributed through a structural design of the coolant storage 210 and the coolant distributor 220, overheating of a specific region and cooling imbalance can be prevented.

In addition, according to the water-cooled coolant distribution device according to the present invention, since a flow path between the lower plate 100 and the coolant distributor 220 is improved, cooling performance can be maximized by quickly removing heat generated during semiconductor chip testing.

In addition, according to the water-cooled coolant distribution device according to the present invention, a manufacturing and assembly process can be simplified, and reliability can be improved through a simple coupling structure of the upper casing 200 and the lower plate 100 and a coolant leakage prevention design using the sealing member (O-ring) 235.

In addition, according to the water-cooled coolant distribution device according to the present invention, cooling efficiency can be further improved by controlling a flow direction of the coolant through a combination of the curved hollow pipe and the linear nozzle, and there is an advantage that maintenance and component replacement of a cooling system are easy due to a structural design of the distribution plate 222 and the distribution plate accommodation groove 228.

In addition, the water-cooled coolant distribution device according to the present invention has advantages of being applied to testing environments of semiconductor chips having various sizes and applied to other electronic devices requiring high performance cooling systems.

According to the water-cooled coolant distribution device according to exemplary embodiments of the present invention, since a coolant is efficiently distributed through a structural design of a coolant storage and a coolant distributor, overheating of a specific region and cooling imbalance can be prevented.

In addition, according to the water-cooled coolant distribution device according to the present invention, since a flow path between a lower plate and a coolant distributor is improved, cooling performance can be maximized by quickly removing heat generated during semiconductor chip testing.

In addition, according to the water-cooled coolant distribution device according to the present invention, a manufacturing and assembly process can be simplified, and reliability can be improved through a simple coupling structure of an upper casing and a lower plate and a coolant leakage prevention design using a sealing member (O-ring).

In addition, according to the water-cooled coolant distribution device according to the present invention, cooling efficiency can be further improved by controlling a flow direction of a coolant through a combination of a curved hollow pipe and a linear nozzle, and there is an advantage that maintenance and component replacement of a cooling system are easy due to a structural design of a distribution plate and a distribution plate accommodation groove.

In addition, the water-cooled coolant distribution device according to the present invention has advantages of being applied to testing environments of semiconductor chips having various sizes and applied to other electronic devices requiring high performance cooling systems.

However, the concept of the present invention is not necessarily limited thereto, and the device/method/system according to exemplary embodiments of the present invention may be applied to various products/technical fields other than the above-described product/technical field.

While various embodiments of the preset invention have been described above in detail, it may be understood by those skilled in the art that the embodiments may be variously modified without departing from the scope of the present invention. Therefore, the scope of the present invention is defined not by the described embodiments but by the appended claims, and encompasses equivalents that fall within the scope of the appended claims.

What is claimed is:

1. A water-cooled coolant distribution device with enhanced cooling efficiency, comprising:
a lower plate;
an upper casing coupled to an upper portion of the lower plate;
an inlet part which is coupled to the upper casing and through which a coolant is introduced from a coolant supply;
an outlet part which is coupled to the upper casing and through which the coolant is discharged toward a coolant collector;
a coolant storage which is disposed in the upper casing to communicate with the inlet part and stores the coolant introduced through the inlet part; and
a coolant distributor disposed on an upper surface of the lower plate to distribute the coolant supplied from the coolant storage in different directions,
wherein the coolant introduced sequentially through the inlet part and the coolant storage is branched by the coolant distributor in the different directions and guided to flow to a space between the lower plate and the coolant distributor.

2. The water-cooled coolant distribution device of claim 1, wherein the coolant distributor includes:
a distribution plate; and
a coolant guide line formed in a central region of the distribution plate,
wherein the coolant guide line is provided as one or more nozzles having a linear shape, which pass through an upper surface and a lower surface of the distribution plate.

3. The water-cooled coolant distribution device of claim 2, wherein the inlet part includes:
a first inlet through which the coolant is introduced from the coolant supply;
a first outlet through which the coolant is discharged toward the coolant storage; and
an inlet line connecting the first inlet and the first outlet,
wherein the inlet line is provided as a curved hollow pipe to change a flow direction of the coolant introduced through the first inlet in a first direction extending horizontally to a second direction extending vertically.

4. The water-cooled coolant distribution device of claim 3, wherein:
a coolant guide groove for branching the coolant supplied from the coolant distributor in two directions is formed in the upper surface of the lower plate; and
the coolant guide groove extends in a third direction perpendicular to each of the first direction and the second direction.

5. The water-cooled coolant distribution device of claim 4, wherein a length of the coolant guide groove extending in the third direction is greater than a length of the distribution plate extending in the third direction.

6. The water-cooled coolant distribution device of claim 3, wherein the coolant guide line is provided as a linear nozzle extending in the first direction and disposed at a location which is not aligned with the first outlet in the second direction.

7. The water-cooled coolant distribution device of claim 2, wherein:
a distribution plate accommodation groove for accommodating an edge portion of the distribution plate is formed in a lower surface of the upper casing; and
the distribution plate is inserted into and coupled to the distribution plate accommodation groove.

8. The water-cooled coolant distribution device of claim 2, further comprising a sealing member which is interposed between the lower plate and the upper casing to prevent leakage of the coolant,
wherein the sealing member is provided as an O-ring having a greater diameter than the coolant distributor.

9. The water-cooled coolant distribution device of claim 8, wherein:
a sealing member accommodation groove for accommodating the sealing member is formed in a lower surface of the upper casing; and
the sealing member is inserted into and coupled to the sealing member accommodation groove.

10. The water-cooled coolant distribution device of claim 3, wherein the outlet part includes:
a second inlet through which the coolant flowing through the coolant distributor is introduced;
a second outlet through which the coolant is discharged toward the coolant collector; and
an outlet line connecting the second inlet and the second outlet,
wherein the outlet line is provided as a curved hollow pipe to change a flow direction of the coolant introduced through the second inlet in the second direction to the first direction.

11. The water-cooled coolant distribution device of claim 10, wherein the distribution plate includes:
a first plate which is divided by the coolant guide line and faces the first outlet; and
a second plate which is divided by the coolant guide line and located at a side opposite to the first plate,
wherein the first plate and the second plate are manufactured in different shapes.

12. The water-cooled coolant distribution device of claim 11, wherein the second plate has a smaller area than the first plate so as not to be aligned with the second inlet in the second direction.
